(19) United States
(12) Patent Application Publication
(10) Pub. No.: US 2025/0188592 A1
(43) Pub. Date: Jun. 12, 2025

(54) HIGH-EFFICIENCY TARGET FOR AN ION SOURCE

(71) Applicant: Axcelis Technologies, Inc., Beverly, MA (US)

(72) Inventors: Joshua Abeshaus, Salem, MA (US); Neil Bassom, Hamilton, MA (US); Neil Colvin, Merrimack, NH (US); Camilla Zimmerman, Beverly, MA (US); Paul Silverstein, Arlington, MA (US); Makita Erni, Peabody, MA (US)

(21) Appl. No.: 18/973,450

(22) Filed: Dec. 9, 2024

Related U.S. Application Data
(60) Provisional application No. 63/608,975, filed on Dec. 12, 2023.

(51) Int. Cl. C23C 14/34; B33Y 10/00; B33Y 70/00; B33Y 80/00

(52) U.S. Cl. CPC C23C 14/3414; B33Y 10/00; B33Y 70/00; B33Y 80/00

(57) ABSTRACT

A target body can define a central bore along a central axis of the target body. The central axis extends between two planar ends of the target body. The target body has an effective density of less than 0.5 in region around the central bore. The target body can be a metal-doped ceramic material including AlN doped with aluminum or a homogenous ceramic material including AlN or Al₂O₃ and may be fabricated using additive manufacturing.

### CROSS-REFERENCE TO RELATED APPLICATIONS

This application claims priority to the provisional patent application filed Dec. 12, 2023, and assigned U.S. App. No. 63/608,975, the entire disclosure of which is hereby incorporated herein by reference.

### FIELD OF THE DISCLOSURE

This disclosure relates to ion implantation and, more specifically, to a target for an ion source.

### BACKGROUND OF THE DISCLOSURE

In the manufacture of semiconductor devices, ion implantation is used to dope semiconductors with impurities. Ion implantation systems are often used to implant a workpiece, such as a semiconductor wafer, with ions from an ion beam to produce n-type or p-type material doping or to form passivation layers during fabrication of an integrated circuit. Such beam treatment can selectively implant the wafers with impurities of a specified dopant material, at a predetermined energy level, and in controlled concentration to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material workpiece, whereas a “p-type” extrinsic material workpiece often results from ions generated with source materials such as boron, gallium, or indium.

A typical ion implanter includes an ion source, an ion extraction device, a mass analysis device, a beam transport device, and a process chamber. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, workpieces are transferred in to and out of the process chamber via a workpiece handling system, which may include one or more robotic arms, for placing a workpiece to be treated in front of the ion beam and removing treated workpieces from the ion implanter.

Ion sources (commonly referred to as arc ion sources) generate ion beams used in ion implanters and can include heated filament cathodes for creating ions that are shaped into an appropriate ion beam to treat a workpiece. For example, an ion source can have a cathode supported by a base and positioned with respect to a gas confinement chamber for ejecting ionizing electrons into the gas confinement chamber. The cathode can be a tubular conductive body having an endcap that partially extends into the gas confinement chamber. A filament can be supported within the tubular body and emits electrons that heat the endcap through electron bombardment, thereby thermionically emitting ionizing electrons into the gas confinement chamber.

A repeller is positioned opposite the cathode. A target can be provided near the repeller. The target is used as a source of ions, which are created by energetic sputtering of the target. Use of fluorine or other reactive species can enhance chemical etching of the material of the target.

### BRIEF SUMMARY OF THE DISCLOSURE

A target for an ion source is provided in a first embodiment. The target includes a target body that defines a central bore along a central axis of the target body. The central axis extends between two planar ends of the target body. The target body has an effective density of less than 0.5 in a region around the central bore. The effective density can be the solid volume of the target divided by the overall volume of the target (i.e., including gaps or openings in the target), but the effective density does not include the volume of the central bore.

The target body may be cylindrical. In an instance, the target body defines at least one circular groove along the central axis of the target body. The circular groove may have a larger diameter than that of the central bore. The target body may include at least two of the circular grooves. The circular grooves may extend only partly into the target body. The target body may include at least one groove around an exterior surface.

The target body may include a lattice structure around the central bore.

The region around the central bore having the effective density of less than 0.5 may extend from the central bore to an exterior surface of the target body opposite the central bore.

The effective density may be less than 0.1.

The target body may have a surface area from 3,000 mm² to 15,000 mm².

The target body may include a metal. In an instance, the target body may be a metal-doped ceramic material including AlN doped with aluminum or a homogenous ceramic material including AlN or Al₂O₃.

The ion source can further include or the target can be used with an arc chamber. The target body is disposed in the arc chamber. A repeller is disposed through the central bore of the target body. An indirectly heated cathode is disposed in the arc chamber opposite of the repeller. A repeller shaft of the repeller may be threadably received within the central bore of the target body.

A method is provided in a second embodiment. The method includes directing a stream of electrons and ions at a repeller and a target body that includes a metal. The target body defines a central bore along a central axis of the target body that the repeller is disposed within. The target body has an effective density of less than 0.5 in region around the central bore. Metal ions are eroded from the target body using the stream of electrons and ions. The eroding may include physical sputtering and/or a chemical reaction.

The target body may be a metal-doped ceramic material including AlN doped with aluminum or a homogenous ceramic material including AlN or Al₂O₃.

The effective density may be less than 0.1.

The target body may have a surface area from 3,000 mm² to 15,000 mm².

A method is provided in a third embodiment. The method includes forming a target body using additive manufacturing. The target body defines a central bore along a central axis of the target body. The central axis extends between two planar ends of the target body. The target body has an effective density of less than 0.5 in region around the central bore. The target body may be a metal-doped ceramic material including AlN doped with aluminum or a homogenous ceramic material including AlN or Al₂O₃.

### DESCRIPTION OF THE DRAWINGS

For a fuller understanding of the nature and objects of the disclosure, reference should be made to the following detailed description taken in conjunction with the accompanying drawings, in which:

FIG. 1 is a cross-sectional view of a target used in an ion source in accordance with an embodiment of the disclosure;

FIG. 2 is a top view of an embodiment of a target in accordance with another embodiment of the disclosure;

FIG. 3 is a top view of an embodiment of a target in accordance with another embodiment of the disclosure;

FIG. 4 is a perspective view of another embodiment of a target;

FIG. 5 is a perspective view of another embodiment of a target;

FIG. 6 is a flowchart of a method in accordance with the present disclosure; and

FIG. 7 is a block diagram of an exemplary vacuum system utilizing an ion source with a target in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

In an ion implanter, a solid target is bombarded with electrons or with electrons and ions and, as a result, ions of the target material are ejected from the target. These ions can be directed toward a workpiece in the ion implanter. This ion bombardment of the target not only causes ions of the target materials to be ejected, but imparts considerable thermal energy to the target itself.

Ion source lifetime during operation is usually limited by erosion of the cathode instead of depletion of the target. The rate of removal of the material in the target is a function of the temperature of the target and the area of target material participating in the reaction. Cathode erosion rates can be determined by the arc currents and voltages used in the ion source. An improved target that runs hotter and provides a larger reaction surface will enable target beam currents to be achieved with lower arc currents and voltages and thereby may reduce the cathode erosion rate.

Embodiments disclosed herein provide a target used for ion implantation that runs hotter and presents a larger reaction area than those previously used. Targets used in sputter sources generally have a cylindrical, tubular, or slab-like shape. Inventor observation shows that reaction rates are higher when the target is in a location where it runs hotter (such as on the cathode-repeller axis). Restricting the cross-section area of the target near the base where it attaches to the ion source is typically advantageous because it restricts the conductive flow of heat out of the target and causes the plasma-facing face to become hotter, which increases the reaction rate. An increased reaction rate can provide improved beam current in an ion beam.

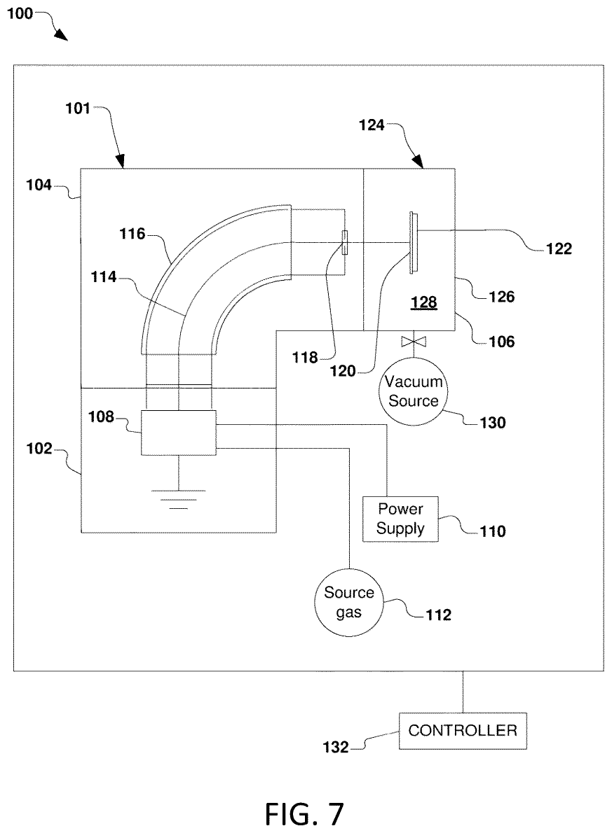

FIG. 7 illustrates an exemplified vacuum system 100 that may implement various apparatus, systems, and methods of the present disclosure. The vacuum system 100 in includes an ion implantation system 101, however various other types of vacuum systems are also contemplated, such as plasma processing systems or other semiconductor processing systems. The ion implantation system 101, for example, comprises a terminal 102, a beamline assembly 104, and an end station 106.

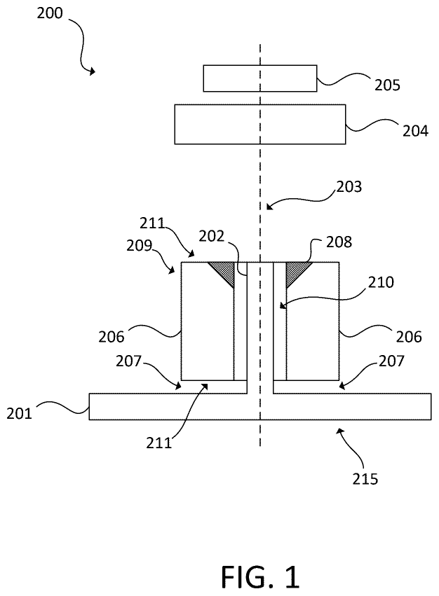

Generally speaking, an ion source 108 in the terminal 102 is coupled to a power supply 110, whereby a gas from a gas source 112 (also called a dopant gas) supplied thereto and/or material from a target (such as that in FIG. 1) is ionized into a plurality of ions to form an ion beam 114. The ion beam 114 is directed through a beam-steering apparatus 116 and out an aperture 118 towards the end station 106. In the end station 106, the ion beam 114 bombards a workpiece 120 (e.g., a semiconductor such as a silicon wafer, a display panel, etc.), which is selectively clamped or mounted to a chuck 122 (e.g., an electrostatic chuck). Once embedded into the lattice of the workpiece 120, the implanted ions change the physical and/or chemical properties of the workpiece 120. Because of this, ion implantation is used in semiconductor device fabrication and in metal finishing, as well as various applications in materials science research.

The ion beam 114 of the present disclosure can take any form, such as a pencil or spot beam, a ribbon beam, a scanned beam, or any other form in which ions are directed toward end station 106, and all such forms are contemplated as falling within the scope of the disclosure.

The end station 106 includes a process chamber 124, such as a vacuum chamber 126, wherein a process environment 128 is associated with the process chamber. The process environment 128 within the process chamber 124, for example, comprises a vacuum produced by a vacuum source 130 (e.g., a vacuum pump) coupled to the process chamber 124 and configured to substantially evacuate the process chamber 124. A controller 132 is provided for overall control of the vacuum system 100.

The embodiments of the present disclosure may be implemented in various semiconductor processing equipment such as CVD, PVD, MOCVD, etching equipment, and various other semiconductor processing equipment, and all such implementations are contemplated as falling within the scope of the present disclosure. The embodiments of the present disclosure further advantageously improve the performance of the ion source 108 and increase overall productivity and lifetime of the vacuum system 100.

The ion source 108 (also called an ion source chamber), for example, can be constructed using refractory metals (W, Mo, Ta, etc.) and graphite in order to provide suitable high temperature performance, whereby such materials are generally accepted by semiconductor manufacturers. The gas from the gas source 112 is used within the ion source 108. The gas may or may not be conductive in nature. However, after the gas is cracked or fragmented, the ionized gas can aid in chemical etching of a target material used for implantation, such as metal-doped ceramic materials (e.g., AlN doped with aluminum) and homogenous ceramic materials (e.g., AlN or Al₂O₃) that are used for aluminum implants. The ion source 108, for example, plays a large role in the ion implantation system 101.

The ion source 108 can use any of the target embodiments disclosed herein. Thus, the ion source 108 can include the components of the ion source 200 or the targets disclosed herein.

FIG. 1 is a cross-sectional view of a target used in an ion source 200. The components of the ion source 200 may be inside an arc chamber (not shown in FIG. 1). A source gas may be injected into the arc chamber during operation.

A filament 205 is heated by current supplied by a power supply (not shown), such that the filament 205 projects thermionic electrons toward the heated cathode 204, which in turn heats the cathode 204 and causes thermionic electrons to be emitted from the cathode 204. The thermionic electrons are projected from the heated cathode 204 along the axis 203. A repeller 201 is positioned opposite the heated cathode 204 along the central axis 203. While illustrated in FIG. 1 as part of an indirectly-heated cathode, the ion source 200 also can use a thermally-heated filament without a cathode 204 or can use a radio frequency (RF) antenna.

The heated cathode 204 is heated to temperatures high enough for it to thermally emit electrons into the arc chamber, which is held at a potential that is positive with respect to the heated cathode 204 to accelerate the electrons. A magnetic field helps confine the electrons along field lines between the heated cathode 204 and repeller 201 to reduce the loss of electrons. The loss of electrons is further reduced by the repeller 201, which can be held at the potential of the heated cathode 204 to reflect electrons back toward the heated cathode 204. The excited electrons ionize material to generate a plasma (not shown). Ions are extracted through an aperture in the arc chamber (not shown) and electrostatically accelerated to form a high energy ion beam by an electrode positioned outside the arc chamber.

In operation, the heated cathode 204 (e.g., a cathode composed of tungsten or tantalum) is indirectly heated via the filament 205 and is used to start and sustain the ion source plasma (e.g., a thermionic electron emission). The heated cathode 204 and the repeller 201, for example, are at a negative potential in relation to other components of the arc chamber, and both the heated cathode 204 and repeller 201 can be eroded by the ionized gases.

A target 209 is positioned around a repeller shaft 202 of the repeller 201. The target 209 has a target body 206 that wraps around the repeller shaft 202 (i.e., both into and out of the page of FIG. 1). In an instance, the target 209 has a central bore 210 that is defined by the target body 206. The central bore 210 can be positioned along the central axis 203. The repeller shaft 202 can be positioned in the central bore 210. In an instance, the central bore 210 is extends between the planar ends 211 of the target body 206. While illustrated as flush with the target body 206, the repeller shaft 202 can extend beyond the target body 206 or can be positioned entirely below an outer surface of the target body 206. In an instance, the repeller shaft 202 of the repeller 201 may be threadably received within the central bore 210 of the target body 206. For example, external threads may be defined on an outer surface of the repeller shaft 202 and internal threads may be defined on an inner surface of the central bore 210, such that the target body 206 can be threaded to the repeller 201 by the external threads of the repeller shaft 202 and the internal threads of the central bore 210.

The target body 206 can be fabricated of a metal-containing material, such as a homogenous ceramic material or a metal-doped ceramic material. For example, the target body 206 can include, consist of, or consist essentially of homogenous AlN or Al₂O₃ or AlN doped with aluminum. In an instance, AlN doped with less than 30% aluminum may increase beam current.

The target body 206 also can include, consist of, or consist essentially of a gallium alloy (e.g., gallium nitride or gallium oxide). Other materials are possible, and these are merely examples. In an instance, the target body 206 is not exclusively a metal. In this case, the metal is a target ion and the target body 206 can be, for example, an insulator.

In an instance, the target body 206 is cylindrical. However, the target body also can be polygonal or other shapes.

A gas flow channel 207 can enable gas flow between the target body 206 and a base 215 of the repeller 201. The gas flow channel 207 also can enable gas flow between the target body 206 and the repeller shaft 202. For example, a gas that includes fluorine (e.g., BF₃ or PF₃) can be used with the gas flow channel 207.

In an instance, an etching gas is fed into the arc chamber with the target 209 through a passage through the target and support structure, such as the gas flow channel 207, which enables a reaction. In an instance, the chemical reaction is between the etchant gas and material in the target 209 assisted by the energy of ions and electrons from the plasma. The primary electrons emitted from the cathode 204 may tend to have less of an effect in this process than positive ions from the plasma because the positive ions have higher mass.

During operation, electrons are projected from the heated cathode 204 and generate a plasma. Material from the target 209 can be eroded from the target body 206 by the electrons and ions from the plasma. The term “erode” herein can include physical and/or chemical aspect. The target body 206 may be preferentially eroded in the regions 208 (shown with hatching).

Embodiments disclosed herein increase the active surface area of the target 209 and improve thermal characteristics of the target 209. In an instance, the target body 206 has an effective density of less than 0.5 in a region around the central bore 210. The effective density can be the solid volume of the target 209 divided by the overall volume of the target 209 (i.e., including gaps or openings in the target 209), but the effective density does not include the volume of the central bore 210. This effective density can include the region between the planar ends 211 from the surface adjacent the central bore 210 to a surface at the outermost diameter from the central axis 203. Thus, the region can extend from the central bore 210 to an exterior surface of the target body 206. The region excludes the volume of the central bore 210 and can border or abut a space of the central bore 210.

Embodiments disclosed herein can provide a more tortuous path for any gas flow through the target 209. A lower conductance of gas means the target 209 will be hotter. The effective density and other design features can affect the gas flow. The longer path gives etchant molecules moving from a back of the target 209 to a front of the target 209 more time and opportunities to hit the surface of the target 209, thereby increasing the reaction rate and/or other erosion. To the extent that the more tortuous path reduces the cross-sectional area to conduct heat away from the target 209 it will increase temperatures.

The effective density of the region of the target body 206 can be less than 0.2 or less than 0.1, including all 0.01 values between 0 and 0.2. Use of these effective density values increases surface area of the target body 206 and reduces conductive heat losses.

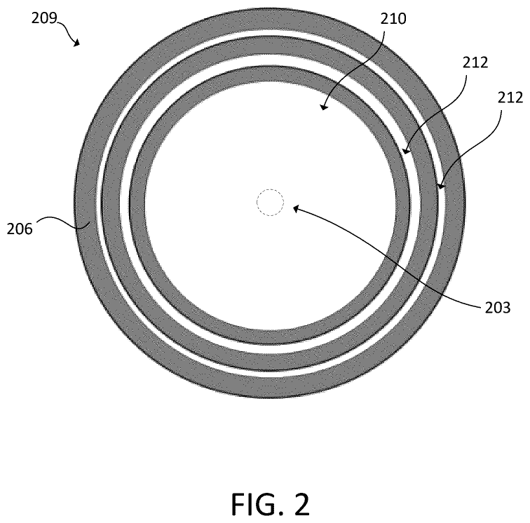

FIG. 2 is a top view of an embodiment of a target 209. The active area of the target 209 in FIG. 2 can be increased by the further removal of material. The target body 206 includes at least one circular groove 212 along the central axis 203 of the target body 206. The circular groove 212 has a larger diameter than that of the central bore 210, which places the circular groove 212 in the target body 206 between the surface adjacent the central bore 210 and a surface at the outermost diameter from the central axis 203.

In the example of FIG. 2, there are two circular grooves 212. However, more than two circular grooves 212 can be added. The grooves 212 can be, for example, 1 mm or larger in a width or depth dimension. The number of grooves 212 can be spaced such that the grooves 212 remain on the target 209 after repeated thermal cycling.

The circular groove 212 may not extend an entire height of the target body 206. Thus, the circular groove 212 may only extend partly into the target body 206. This configuration can conduct heat to the mounting structure while supporting the cylinders of the target body 206 with a minimal amount of physical connections.

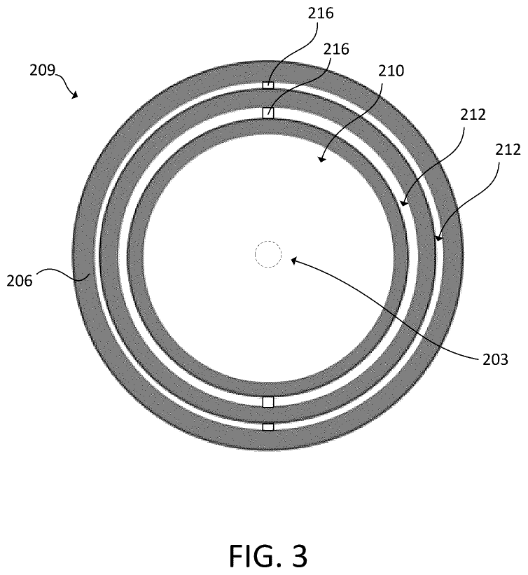

In another embodiment, the target 209 may have a series of concentric cylinders held together by support struts 216, which is shown in FIG. 3. The support struts 216 may be fabricated of the same material as the target 209 or a different material. For example, the support struts 216 can be fabricated of an insulator.

Since physical connections between the cylinders of the target body 206 are minimized, heat conduction from the hottest central region in the embodiment of FIGS. 2 and 3 is restricted and each cylinder acts as a radiation shield for the inner cylinders. This increases the temperature of the most active regions in the center. Thus, the region closest to the central axis 203 in the central bore 210 tends to be the hottest.

Instead of or in addition to the circular groove 212, a cylindrical hole can be drilled or otherwise formed partly or fully through the target body 206. These cylindrical holes can be parallel to the central axis. The cylindrical holes may have a symmetrical arrangement around the target body 206. The holes may be 1-10 mm in diameter.

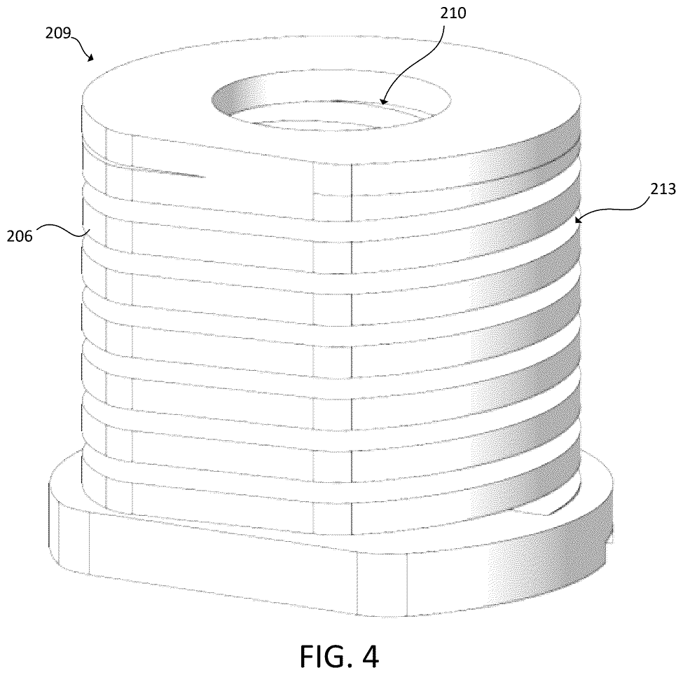

FIG. 4 is a perspective view of another embodiment of a target. The target body 206 includes at least one groove 213 around an exterior surface of the target body 206. The groove 213 can wrap around the exterior surface of the target body 206 in a spiral or corkscrew pattern. A groove 213 also can wrap around an interior surface of the target body 206, such as in the central bore 210. Placement of a groove 213 in the central bore 210 can restrict gas flow. While one groove 213 is illustrated, multiple grooves 213 can be used on each surface in a separated or interwoven pattern. The groove 213 increases the surface area of the target body 206 and reduces thermal losses by forming the target body 206 from a single piece of material. In another embodiment, the groove 213 extends entirely through the target body 206 from the exterior surface to the central bore 210, so that target body 206 resembles a spring.

The grooves 213 can have a tight spacing that provides more turns of the spiral along the length of the target body 206, thus providing more surface area and making the front surfaces of the target body 206 hotter because the heat flow along a longer path to get to the back of the target body 206. Tight spacing also be useful in reducing the loss of etchant gas through the sides of the target body 206, forcing it to flow over the hottest areas.

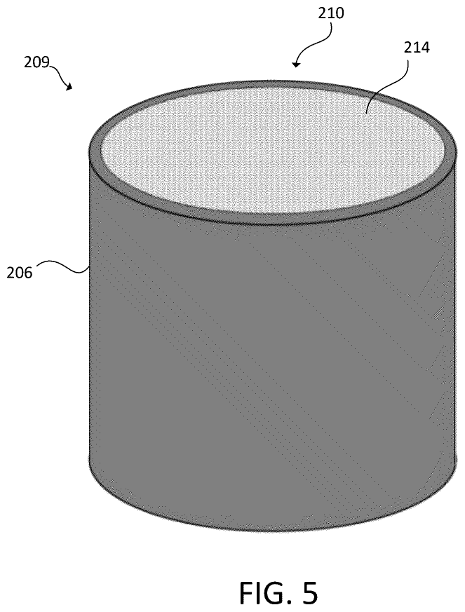

FIG. 5 is a perspective view of another embodiment of a target. A lattice structure 214 is disposed in the central bore 210 of the target body 206. The lattice structure 214 may be foam-like. The lattice structure can have a high surface area and low connectivity for thermal conduction. While not illustrated, a central bore 210 can be formed for placement of the repeller shaft 202 in FIG. 1. The central bore 210 can extend through the center of the target body 206. The target body 206 also can function as a cap for the part of the target body 206 facing a repeller.

The lattice structure 214 can be additively manufactured to have intertwined surfaces, forming a continuous channel for fluid flow between them. This maximizes the area of target 209 available for reactions. Gas can be fed into one end of the target 209 and pass over the entire structure before emerging from the opposite end of the target 209 into the arc chamber. The geometry of the lattice structure 214 can be configured for a particular application, such as for a particular lattice structure 214 material or a specific implant process.

The lattice structure 214 can reduce the weight of the target 209 while maintaining its mechanical properties. The lattice structure 214 can change the effective cross-sectional area and volume of the target 209, which will affect its thermal properties. The lattice structure 214 may be a space-filling unit cell that can be tessellated along any axis with no gaps between cells. The lattice structure 214 can include nodes, beams, and cells.

The lattice structure 214 can take various forms. The lattice structure 214 may be one or more of a volume, surface, graph, triply periodic minimal surface (TPMS), stochastic structures, or rib grids. A gyroid lattice is an example of a TPMS lattice. The size and packing density of the lattice structure 214 can be configured to provide desired characteristics. The lattice structure 214 also may be optimized for fluid conditions. For example, the lattice structure 214 can include a large surface area defining hollow regions with a torturous path that increases the interactions between a gas and the solid. Increased surface area and the torturous path can increase reactions and/or other erosion between the gas and the solid.

The lattice structure 214 can provide sufficient strength during thermal cycling to avoid cracking. The target 209 is bombarded at high temperature, which can increase stress on the lattice structure 214.

The various embodiments of FIGS. 2-5 can be combined or used separately.

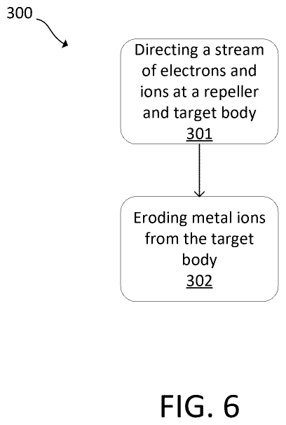

FIG. 6 is a flowchart of a method 300, which can use any of the embodiments disclosed herein. At 301, a stream of electrons and ions is directed at a repeller 201 and a target body 206 that includes a metal, such as a homogenous ceramic material (e.g., AlN or Al₂O₃) or a metal-doped ceramic material (e.g., AlN doped with aluminum). The target body 206 has an effective density of less than 0.5 in region around the central bore 210. Metal ions are eroded from the target body 206 using the stream of electrons and ions at 302. These metal ions can then be used in ion implant application. The eroding can include physical sputtering and/or a chemical reaction.

The geometry of the embodiments of FIGS. 2-5 can be configured to provide desired thermal characteristics. Since the etchant rate is dependent on temperature, increasing the temperature profile can be beneficial. Increasing temperature profile toward a center of the arc chamber for a given input and output boundary condition can provide improved performance. The temperature profile can be linear or non-linear. For example, the temperature profile may be logarithmic with only a small cold section in the target 209.

The thermal conduction may be limited through the front of the target 209, such as through a side of the target body 206 with the regions 208, as shown in FIG. 1. A lower effective density may reduce conduction. Radiative heat transfer along the outer radius or the front also can be reduced through shielding.

In an instance, a reaction and/or other erosion occurs at the front of the target 209, such as the planar end 211 around the regions 208 in FIG. 1. Conductive heat transfer may occur out the opposite side of the target 209, such as the planar end 211 by the gas flow channel 207 in FIG. 1. The heat transfer profile may not be uniform from the front to the back of the target 209. For example, there may be a temperature gradient along the target 209.

The surface area of the target body 206 can be increased by a factor of greater than or equal to 2, greater than or equal to 3, greater than or equal to 10, greater than or equal to 30, or greater than or equal to 100 compared to the surface area of previous targets. Previous targets are cylindrical targets that only include a central bore and typically have an area from approximately 10-100 cm². A larger surface area can result in a more tortuous path for any gas flow through the target 209.

In an example, a standard target design may have a surface area of 3,600 mm². This standard target design may be a solid cylinder. In an instance, the target 209 may have a surface area of 10,000 mm². Thus, the surface area of the target 209 may be two or three times greater than that of a standard target design. The surface area of the target 209 may be from 3,000 mm² to 15,000 mm². The increased surface area can increase the number of reactions during operation and can provide more gas collisions because of the torturous path.

Embodiments of the target body disclosed herein can be formed using machining, chemical etching, and/or additive manufacturing. Additive manufacturing processes are available for many metal-containing materials.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A target for an ion source comprising:
a target body that defines a central bore along a central axis of the target body, wherein the central axis extends between two planar ends of the target body, and wherein the target body has an effective density of less than 0.5 in a region around the central bore.

2. The target of claim 1, wherein the target body is cylindrical.

3. The target of claim 2, wherein the target body defines at least one circular groove along the central axis of the target body, wherein each circular groove has a larger diameter than that of the central bore.

4. The target of claim 3, wherein the target body includes at least two circular grooves.

5. The target of claim 3, wherein each circular groove extends only partly into the target body.

6. The target of claim 2, wherein the target body includes at least one groove around an exterior surface.

7. The target of claim 1, wherein the target body includes a lattice structure around the central bore.

8. The target of claim 1, wherein the region extends from the central bore to an exterior surface of the target body opposite the central bore.

9. The target of claim 1, wherein the effective density is less than 0.1.

10. The target of claim 1, wherein the target body has a surface area from 3,000 mm² to 15,000 mm².

11. The target of claim 1, wherein the target body is a metal-doped ceramic material including AlN doped with aluminum or a homogenous ceramic material including AlN or Al₂O₃.

12. The target of claim 1, further comprising:
an arc chamber, wherein the target body is disposed in the arc chamber;
a repeller disposed through the central bore of the target body; and
an indirectly heated cathode disposed in the arc chamber opposite of the repeller.

13. The target of claim 12, wherein a repeller shaft of the repeller is threadably received within the central bore of the target body.

14. A method comprising:
directing a stream of electrons and ions at a repeller and a target body that includes a metal, wherein the target body defines a central bore along a central axis of the target body that the repeller is disposed within, and wherein the target body has an effective density of less than 0.5 in region around the central bore; and
eroding metal ions from the target body using the stream of electrons and ions.

15. The method of claim 14, wherein the eroding includes physical sputtering and/or a chemical reaction.

16. The method of claim 14, wherein the target body is a metal-doped ceramic material including AlN doped with aluminum or a homogenous ceramic material including AlN or Al₂O₃.

17. The method of claim 14, wherein the effective density is less than 0.1.

18. The method of claim 14, wherein the target body has a surface area from 3,000 mm² to 15,000 mm².

19. A method comprising:
forming a target body using additive manufacturing, wherein the target body defines a central bore along a central axis of the target body, wherein the central axis extends between two planar ends of the target body, and wherein the target body has an effective density of less than 0.5 in region around the central bore.

20. The method of claim 19, wherein the target body is a metal-doped ceramic material including AlN doped with aluminum or a homogenous ceramic material including AlN or Al₂O₃.
